(19) United States
(12) Patent Application Publication
(10) Pub. No.: US 2014/0252571 A1
(43) Pub. Date: Sep. 11, 2014

(54) WAFER-LEVEL PACKAGE MITIGATED UNDERCUT

(71) Applicant: Maxim Integrated Products, Inc., (US)

(72) Inventors: Viren Khandekar, Flower Mound, TX (US); Craig Laughlin, Copper Canyon, TX (US); Tiao Zhou, Carrollton, TX (US)

(73) Assignee: Maxim Integrated Products, Inc., San Jose, CA (US)

(21) Appl. No.: 13/786,584

(22) Filed: Mar. 6, 2013

(51) Int. Cl. H01L 23/00; H01L 23/495

(52) U.S. Cl. CPC H01L 24/05; H01L 23/49582; H01L 24/03
USPC 257/666; 257/762; 438/656

(57) ABSTRACT

A wafer-level package device and techniques are described that include utilizing a dry-etch process for mitigating metal seed layer undercut. In an implementation, a process for fabricating the wafer-level package device that employs the techniques of the present disclosure includes processing a substrate, depositing a metal seed layer on the substrate, depositing and patterning a resist layer, depositing a redistribution layer structure, removing the photoresist layer, and dry-etching the metal seed layer. In implementations, the wafer-level package device that employs example techniques in accordance with the present disclosure includes a substrate, a metal seed layer disposed on the substrate, and a redistribution layer structure formed on the metal seed layer. The metal seed layer is dry-etched so that undercut is mitigated.

### BACKGROUND

Over the years, packaging technologies have evolved to develop smaller, cheaper, more reliable, and more environmentally-friendly packages. For example, chip-scale packaging technologies have been developed that employ direct surface mountable packages having a surface area that is no greater than 1.2 times the area of the integrated circuit chip. Wafer-level packaging (WLP) is a chip-scale packaging technology that encompasses a variety of techniques whereby integrated circuit chips are packaged at wafer-level, prior to segmentation. Wafer-level packaging extends the wafer fabrication processes to include device interconnection and device protection processes. Consequently, wafer-level packaging streamlines the manufacturing process by allowing for the integration of wafer fabrication, packaging, testing, and burn-in processes at the wafer-level.

Traditional fabrication processes used in the manufacture of semiconductor devices employ microlithography to pattern integrated circuits onto a circular wafer formed of a semiconductor such as silicon, gallium arsenide, and so forth. Typically, the patterned wafers are segmented into individual integrated circuit chips or dies to separate the integrated circuits from one another. The individual integrated circuit chips are assembled or packaged using a variety of packaging technologies to form semiconductor devices that may be mounted to a printed circuit board.

### SUMMARY

A semiconductor device and fabrication technique are described that employ wafer-level packaging techniques utilizing a dry-etch process (e.g., plasma-etching) for mitigating (e.g., reducing, minimizing and/or eliminating) metal seed layer undercut. Large array devices may thus be provided, while maintaining the benefits inherent in wafer-level packaging (e.g., lower cost, smaller package size, high pin count, etc.). In an implementation, a process for fabricating the wafer-level package device that employs the techniques of the present disclosure includes processing a substrate, depositing a metal seed layer on the substrate, depositing and patterning a resist layer, depositing a redistribution layer structure, removing the photoresist layer, and dry-etching the metal seed layer. In implementations, a wafer-level package device that employs example techniques in accordance with the present disclosure includes a substrate, a metal seed layer disposed on the substrate, and a redistribution layer structure formed on the metal seed layer. The metal seed layer is dry etched so that undercut is mitigated.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DRAWINGS

The detailed description is described with reference to the accompanying figures. The use of the same reference numbers in different instances in the description and the figures may indicate similar or identical items.

FIG. 1 is a diagrammatic partial cross-sectional side elevation view illustrating a wafer-level package device in accordance with an example implementation of the present disclosure, wherein the wafer-level package device includes a substrate, a metal seed layer that has been etched utilizing a dry-etch process, and a redistribution layer structure.

FIG. 2 is a flow diagram illustrating a process in an example implementation for fabricating a wafer-level package device, such as the device shown in FIG. 1.

FIGS. 3A through 3D are diagrammatic partial cross-sectional side elevation views illustrating the fabrication of a wafer-level package device, such as the device shown in FIG. 1, in accordance with the process shown in FIG. 2.

### DETAILED DESCRIPTION

### Overview

Wafer-level packaging is a chip-scale packaging technology that encompasses a variety of techniques whereby integrated circuit chips are packaged at wafer-level, prior to segmentation. Wafer-level packaging extends the wafer fabrication processes to include device interconnection and device protection processes. Consequently, wafer-level packaging streamlines the manufacturing process by allowing for the integration of wafer fabrication, packaging, testing, and burn-in processes at the wafer-level. Compared to some packaging techniques, wafer-level packaging is generally less costly to implement since packaging occurs at wafer-level, while other types of packaging is performed at strip level. However, large array wafer-level package devices include challenges such as redistribution layer routing, which is driven by line/space design rules, and board-level reliability, which can be affected by thermo-mechanical stress.

Some of these challenges in large array wafer-level package devices may be at least partially caused by metal seed layer undercut. In baseline wafer-level processes, metal seed layer undercut often results from wet-etching because of over-etching performed to ensure a margin against leakage. When the metal seed layer includes an undercut, cracks in subsequent device layers often initiate at or near the undercut location resulting in decreased board level reliability.

Accordingly, a wafer-level package device and techniques are described that include utilizing a dry-etch process for mitigating (e.g., reducing, minimizing, and/or eliminating) metal seed layer undercut. Large array devices may thus be provided while maintaining the benefits inherent in wafer-level packaging (e.g., lower cost, smaller package size, high pin count, etc.). In an implementation, a process for fabricating the wafer-level package device that employs the techniques of the present disclosure includes processing a substrate, depositing a metal seed layer on the substrate, depositing and patterning a resist layer, depositing a redistribution layer structure, removing the photoresist layer, and dry-etching the metal seed layer. In implementations, the wafer-level package device that employs example techniques in accordance with the present disclosure includes a substrate, a metal seed layer disposed on the substrate, and a redistribution layer structure formed on the metal seed layer. The metal seed layer is dry-etched so that undercut is mitigated.

### Example Implementations

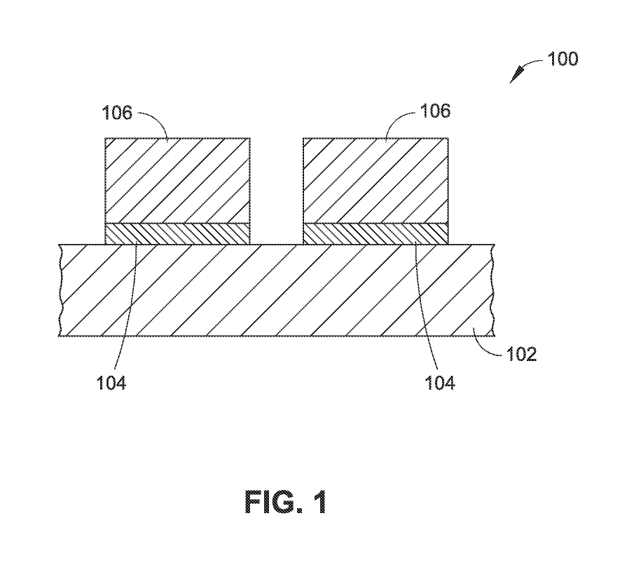

FIG. 1 illustrates a wafer-level package device 100 in accordance with example implementations of the present disclosure. As shown, the wafer-level package device 100 includes a substrate 102. The substrate 102 may include a variety of materials. For example, the substrate 102 may include a passivation material, a dielectric material, and/or a semiconductor material (e.g., a semiconductor device surface). In implementations, the substrate 102 may include a dielectric material (e.g., polybenzoxazole (PBO) or other photodefinable dielectric film). In this implementation, the dielectric material may function to support subsequent layers as well as serve as an electrical insulator. In other implementations, the wafer-level package device 100 may include a substrate 102, such as a dielectric film formed on a wafer-level integrated circuit package device. In these implementations, the wafer-level package device 100 includes a substrate 102, sometimes including one or more integrated circuits formed therein. The substrate 102 may include as a portion of a semiconductor wafer substrate, such as a silicon wafer (e.g., p-type wafer, n-type wafer, and so forth), a germanium wafer, and so forth, that includes one or more integrated circuits formed therein. The integrated circuits may be formed through suitable front-end-of-line (FEOL) fabrication techniques near the surface of the semiconductor wafer substrate. In various implementations, the integrated circuits may include digital integrated circuits, analog integrated circuits, mixed signal integrated circuits, combinations thereof, and so forth. The integrated circuits may be formed through suitable front-end-of-line (FEOL) fabrication techniques.

As shown in FIG. 1, the wafer-level package device 100 includes a metal seed layer 104 disposed on the substrate 102. In implementations, the metal seed layer 104 includes a metallization layer formed over a semiconductor wafer, or as shown in FIG. 1, a substrate 102. The metal seed layer 104 functions to provide a low-resistance electrical path (often for enabling uniform electroplating over a substrate surface), to suitably adhere to the substrate surface (often to an oxide-containing dielectric film, for example PBO), and/or to be otherwise compatible with subsequent electroplating processes. In an embodiment, the wafer-level package device 100 includes a titanium metal seed layer formed on a substrate 102, the substrate 102 including a polybenzoxazole (PBO) film. In this embodiment, titanium is used because of its good adhesion to other materials, its ability to reduce native oxides, and its good electrical contacting properties. Further, the titanium in this implementation may be deposited by sputtering, which is further discussed below. In other embodiments, the metal seed layer 104 may include other metals or metal alloys, for example copper and aluminum. In implementations, the metal seed layer 104 may be deposited using physical vapor deposition methods (e.g., sputtering, ion plating, or evaporation) as well as chemical vapor deposition methods. Subsequent to formation of the redistribution layer structure 106 and a dry-etch step, the metal seed layer 104 is substantially flush with the subsequently formed layers (e.g., redistribution layer) on the metal seed layer 104 (e.g., the side surface of the metal seed layer 104 exposed after the dry-etch step is substantially flush or flat with the redistribution layer structure). The dry-etch step, discussed further below, results in a substantially mitigated undercut of the metal seed layer 104, which improves redistribution layer line/space scaling capability, enables larger arrays, and improves board-level reliability (e.g., reduces thermo-mechanical stress). For example, thermo-mechanical stresses often cause a crack to initiate at a point of undercut of the metal seed layer 104. Undercut of the metal seed layer 106 may include an unintended and/or excessive removal of material (e.g., often at the base of the redistribution layer structure 106) during a wet-etching process. In a specific embodiment illustrating undercut, a metal seed layer 106 with a width of approximately 22 μm is wet-etched resulting in an undercut of approximately 3 μm on each exposed side of the metal seed layer 106 between the redistribution layer structure 106 and the substrate 102. Using a dry-etch process for etching the metal seed layer 104 mitigates the undercut in this specific embodiment and thus avoids cracks initiated at an undercut section of the metal seed layer 104.

The wafer-level package device 100 further includes a redistribution layer structure 106 formed on the metal seed layer 104. In implementations, the redistribution layer structure 106 includes a redistribution layer with metal lines, where the redistribution layer functions as a rerouting and interconnection system that redistributes electrical interconnections in the wafer-level package device 100. In some implementations, a redistribution layer electrically interconnects a conductive pad disposed on an integrated circuit with another component (e.g., a solder bump). The redistribution layer structure 106 may also include other related components, such as under-bump metallization (UBM), contact pads, etc. In some implementations, the redistribution layer structure 106 may include a patterned metal thin-film line (e.g., aluminum, copper, etc.). In one specific implementation, the redistribution layer structure 106 includes a patterned thin-film copper line that has been electroplated on the metal seed layer 104. The redistribution layer structure 106 may be electrically isolated from the substrate 102 and other components except for connections to, for example, bond pads, pillars, or metal runs. In another specific implementation, a wafer-level package device 100 includes a semiconductor wafer where each device is configured to have a titanium metal seed layer 104 etched with a plasma-etch process, which is further discussed below. In this specific implementation, each semiconductor device is designed to include a 20×20 solder ball grid array (e.g., including 400 solder balls). The dry-etch process utilized in this implementation allows the redistribution layer structure 106 to achieve a suitable line/space scaling capability for a 20×20 solder ball grid array because of substantially mitigated undercutting of the titanium metal seed layer 104. In a similar embodiment, a titanium seed layer is dry-etched resulting in a semiconductor device that is designed to include a 16×16 solder ball grid array with a 0.4 mm pitch. In one specific implementation, a redistribution layer structure 106 is formed on the metal seed layer 104 that includes a copper metal line that is approximately 10 μm at its highest point and approximately 20 μm at its widest point. Utilizing a dry-etch process enables smaller redistribution metal lines that are approximately 20 μm or below, where wafer-level package devices that are wet-etched are not capable of achieving redistribution metal lines with widths below 20 μm. In another specific implementation, a redistribution layer structure 106 is formed on the metal seed layer 104 that includes a metal line that is approximately 12 μm at its widest point. These embodiments are not intended to be limiting and are merely examples—other sizes and dimensions may be utilized in forming a redistribution layer structure 106.

Subsequent to forming the redistribution layer structure 106, additional layers may be added to the wafer-level package device 100 beyond the redistribution layer structure 106 (e.g., electrical interconnections, encapsulation layers, dielectric and/or passivation layers, and/or layers configured to function as structural support). Further, the wafer-level package device 100 may be singulated into individual semiconductor devices subsequent to the formation of additional layers and coupled to a printed circuit board (not shown), thereby forming an electronic device. A printed circuit board may include a circuit board used to mechanically support and electrically connect electronic components (e.g., the individual semiconductor devices) using conductive pathways, tracks or signal traces etched from copper sheets laminated onto a non-conductive substrate.

### Example Fabrication Processes

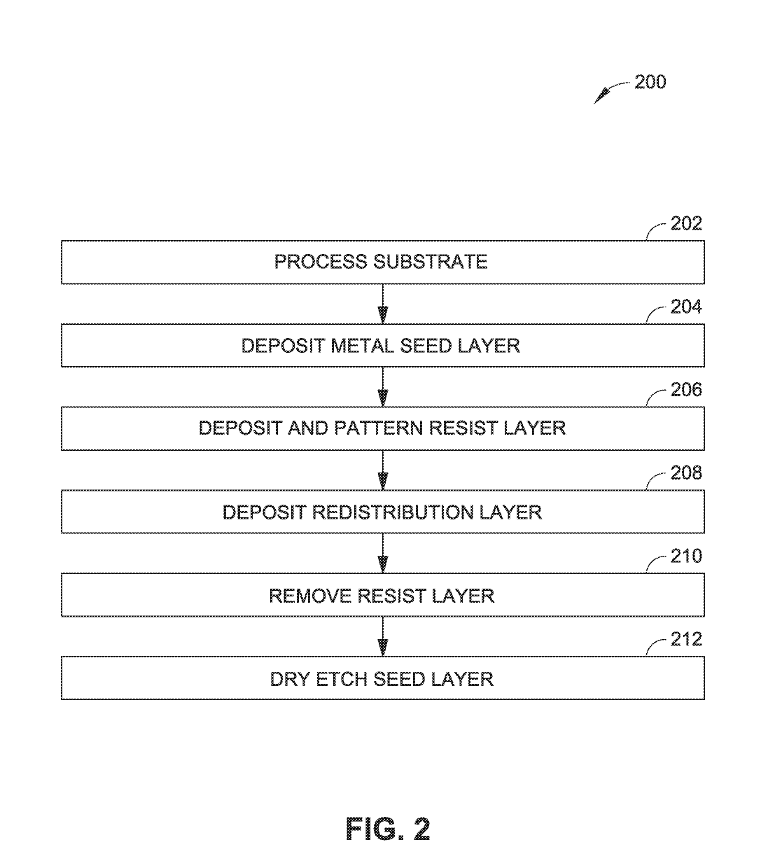

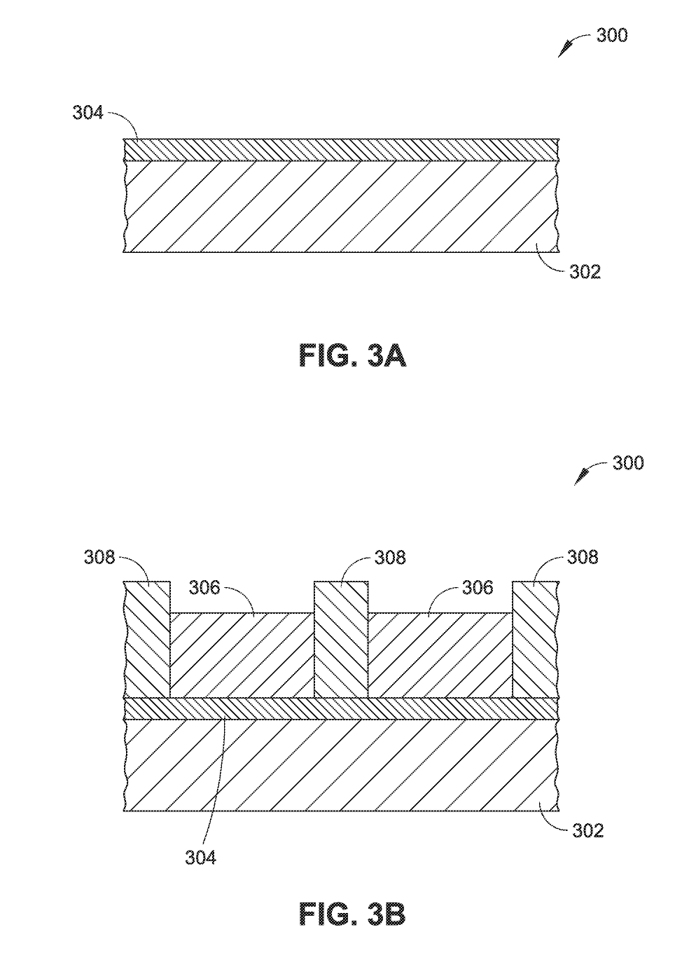

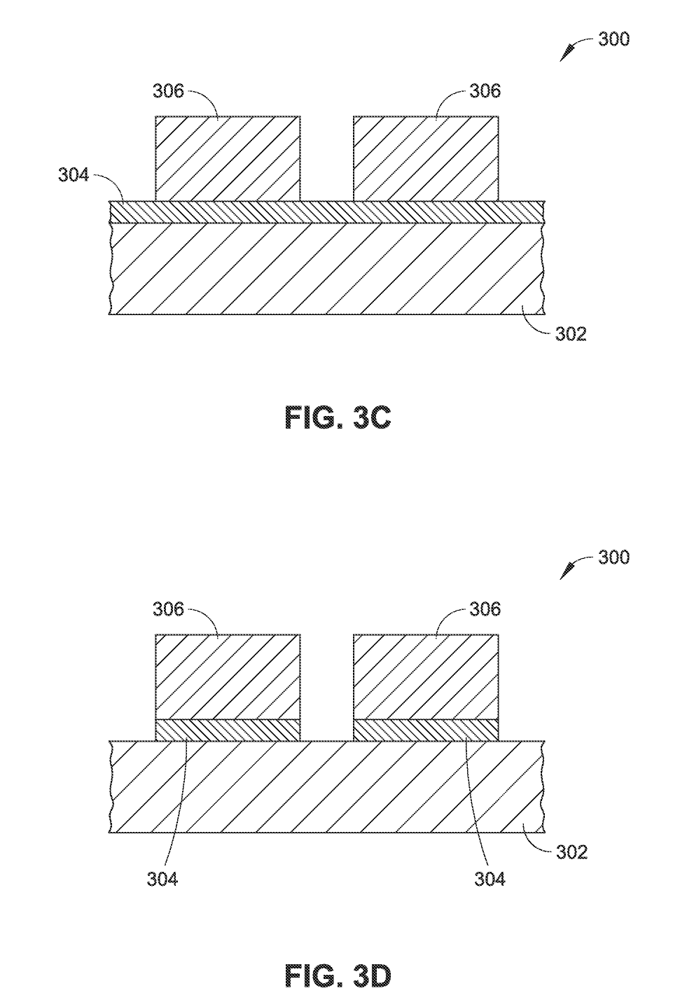

FIG. 2 illustrates an example process 200 that employs wafer-level packaging techniques to fabricate semiconductor devices including a mitigated undercut metal seed layer 104, such as the wafer-level package device 100 shown in FIG. 1. FIGS. 3A through 3D illustrate sections 300 of an example mitigated undercut metal seed layer 304 that is utilized to fabricate semiconductor devices (such as wafer-level package device 100 shown in FIG. 1).

Accordingly, a substrate is processed (Block 202). FIG. 3A illustrates a portion of the substrate 302, which, when processed through suitable FEOL fabrication techniques, includes a passivation and/or a dielectric layer (e.g., a photodefinable dielectric film) and/or a semiconductor substrate that includes one or more integrated circuits formed therein. In an implementation, processing the substrate 302 includes forming a dielectric film (e.g., polybenzoxazole (PBO)) on the surface of an integrated circuit. In this implementation, the dielectric film may act to support subsequent layers as well as act as an electrical insulator. In implementations, forming a dielectric film includes spin coating a layer of the dielectric film on the substrate 302. In other implementations, forming the dieletric film includes other deposition techniques, such as physical vapor deposition (e.g., sputtering) and chemical vapor deposition. The processed integrated circuits may be configured in a variety of ways. For example, processing the integrated circuits may include processing digital integrated circuits, analog integrated circuits, mixed-signal integrated circuits, etc. The processed integrated circuits are connected to one or more conductive layers (e.g., bump interfaces, redistribution layers, etc.) that provide electrical contacts through which the integrated circuits are interconnected to other components associated with the substrate 302. Additionally, the substrate 302 may be processed at a location separate from the other process steps.

A metal seed layer is deposited on the substrate (Block 204). FIG. 3A illustrates depositing a metal seed layer 304 on a substrate 302. In implementations, depositing the metal seed layer 304 may include using a “dry” technique, such as by physical vapor deposition (“PVD”) including sputtering (e.g., DC and/or RF plasma sputtering, bias sputtering, magnetron sputtering, or Ionized Metal Plasma (IMP) sputtering), ion plating, or evaporation), or by chemical vapor deposition (“CVD”) (e.g., thermal CVD, Plasma Enhanced CVD (“PECVD”), Low Pressure CVD (“LPCVD”), High Pressure CVD (“HPCVD”), and Metallo Organic CVD (“MOCVD”). In some implementations, depositing the metal seed layer 304 may include depositing using a “wet” electroless plating process. In one implementation, depositing a metal seed layer 304 includes sputtering a titanium metal seed layer on a substrate 102 (e.g., a polybenzoxazole (PBO) film). When titanium is the metal chosen for deposition, it is often deposited using a standard magnetron sputtering process or by using collimated or ionized sputtering. Sputtering includes ejecting material from a target (i.e., the source of the material being deposited) onto the substrate 302 (e.g., a layer of PBO). Other materials, such as copper, silver, tungsten, aluminum, and alloys may also be suitable for use in depositing the metal seed layer 304 on the substrate 302.

Next, a resist layer is deposited and patterned on the metal seed layer (Block 206). As illustrated in FIG. 3B, a resist layer 308 is deposited and patterned on the metal seed layer 304 for subsequently forming a redistribution layer structure 306. In implementations, depositing and patterning a resist layer 308 may utilize photolithography techniques. Photolithography includes utilizing light to transfer a geometric pattern from a photomask to a light-sensitive chemical resist layer 308 (e.g., a photoresist) on the substrate 302. In implementations, the metal seed layer 304 is covered with a resist layer 308 by spin coating a light-sensitive resist material (e.g., a photoresist) on the wafer-level package device 100. In implementations, spin coating includes dispensing a viscous, liquid solution of resist material onto the wafer, and the wafer is spun rapidly to produce a uniformly thick layer of the resist material. The spin coating process results in a substantially uniform thin layer of resist material, often with uniformity in the range of approximately 5 to 10 nanometers. The pattern in the resist layer 308 is created by exposing it to light either directly (e.g., without using a mask) or with a projected image using an optical mask. The exposure to light causes a chemical change that allows a portion of the photoresist (e.g., corresponding with the desired pattern) to be removed by a developer solution. In one implementation, depositing and patterning a resist layer 308 includes spin coating a photoresist on the metal seed layer 304, exposing a portion of the photoresist to light using a mask, and removing the exposed portion of the resist layer 308 (e.g., photoresist) with a developer solution. In this implementation, the remaining portion of the patterned area (e.g., the portion unexposed to the light) of the resist layer 308 functions as a pattern for subsequently forming a redistribution layer structure 304. In some implementations, the unexposed portion of the resist layer 308 is the portion that is removed while the exposed portion is the portion that remains.

A redistribution layer structure is then deposited (Block 208). As shown in FIG. 3B, the redistribution layer structure 306 is deposited in the patterned area created by the removed portion of the resist layer 308. Forming the redistribution layer structure 306 may include forming a redistribution layer as well as forming corresponding bonding pads, underbump metallization (UBM), through-silicon vias (TSVs), wiring and/or metal layers, and other electrical interconnections. In implementations, forming a redistribution layer structure 306 includes forming a redistribution layer that includes an UBM and a bonding pad. Forming the redistribution layer structure 306 may include forming a conductive material, such as polysilicon, or a metal, such as aluminum or copper, which may be applied over a passivation layer or an isolation layer. In one specific implementation, copper is deposited as the metal line in a redistribution layer structure 306. In this implementation, depositing a copper redistribution layer structure 306 may include utilizing an electroplating process. Copper may be electrolytic plated by using external electrodes an applied current. Electroplating the copper may include mounting the wafer-level package device 100 on a cathode and immersed the wafer-level package device 100 into a plating solution that contains copper ions. An inert anode (e.g., a platinum anode) is also immersed into the copper ionic solution. A voltage is applied between the two electrodes and the current drives the copper ions toward the wafer-level package device 100 thereby forming metallic copper (e.g., the metal lines of the redistribution layer structure 306) on the metal seed layer 304. In other implementations, depositing a copper redistribution layer structure 306 may include electroless plating (i.e., deposition without an applied field), physical vapor deposition methods (e.g., sputtering, evaporation, etc.), and/or chemical vapor deposition methods.

After deposition of the redistribution layer structure, the remaining resist layer is no longer needed and is removed from the substrate (Block 210), leaving the desired layer(s) (e.g., the redistribution structure 306). As shown in FIG. 3C, the patterned resist layer 308 remaining between the deposited redistribution layer structure 306 is removed. In implementations, removing the resist layer 308 often utilizes a liquid resist stripper, which chemically alters the resist layer 308 so that it no longer adheres to the metal seed layer 304. In other implementations, removing the resist layer 308 may include ashing, which involves using a plasma containing oxygen and oxidizes the resist layer 308.

Subsequent to removing the resist layer, the metal seed layer is dry-etched (Block 212). As illustrated in FIG. 3D, the metal seed layer 304 is dry-etched to remove the portion of the metal seed layer 304 in the trenches between the deposited redistribution layer structures 306 and disposed on the substrate 302. In implementations, a metal seed layer 304 is plasma-etched resulting in removal of a portion of the metal seed layer 304 (e.g., the portion directly below the remaining resist layer before the remaining resist layer is removed) and the exposed sides (e.g., the sides exposed after dry-etching) of the metal seed layer 304 being substantially flush (e.g., level and/or in the same plane) with a corresponding (e.g., directly adjacent, contacting, and/or next to) side or edge of the redistribution layer structure 304. Plasma etching may include a high-speed stream of glow discharge (e.g., plasma) from a gas mixture directed at the metal seed layer 304 as a wafer-level package device 100 is processed. The plasma source, known as the etch species, can be either charged (e.g., ions) or neutral (e.g., atoms and radicals). During the process, the plasma generates volatile etch products from the chemical reactions between the elements of the material etched (e.g., the metal seed layer 301, titanium for example) and the reactive species generated by the plasma. The etched material is removed using a discharge gas. Dry-etching prevents subsequent issues related to board level reliability because dry-etching (e.g., plasma-etching) is an anisotropic or directional process and substantially eliminates undercut in the metal seed layer 304. Anisotropic etching is needed to minimize underetching the metal seed layer 304 and etch bias. The anisotropic etching is due to the presence of ionic species in the plasma and the electric fields that direct them normal to the surface of the wafer-level package device 100. In some implementations, utilizing a dry-etch process mitigates an undercut of approximately 2-3 μm (i.e., often the amount of undercut resulting from other wet-etch processes). Additionally, zero undercut of the metal seed layer results in improved redistribution layer line/space scaling capabilities.

Once the dry-etching process is complete, suitable processes may be employed to add additional layers and wafer-level package device 100 components and segment the individual integrated circuit chips of the wafer-level package device 100 into individual packages.

### Conclusion

Although the subject matter has been described in language specific to structural features and/or process operations, it is to be understood that the subject matter defined in the appended claims is not necessarily limited to the specific features or acts described above. Rather, the specific features and acts described above are disclosed as example forms of implementing the claims.

What is claimed is:

1. A wafer-level package device, comprising:
a substrate;
a metal seed layer disposed on the substrate;
a redistribution layer structure disposed on the metal seed layer, where the metal seed layer has been dry-etched and at least one exposed edge of the metal seed layer is at least substantially flush with a corresponding exposed edge of the redistribution layer structure.

2. The wafer-level package device as recited in claim 1, wherein the substrate includes a photodefinable dielectric film.

3. The wafer-level package device as recited in claim 1, wherein the metal seed layer includes a titanium seed layer.

4. The wafer-level package device as recited in claim 1, wherein the redistribution layer structure includes a plated copper redistribution layer structure.

5. The wafer-level package device as recited in claim 1, wherein the redistribution layer structure includes a redistribution layer metal line with a width less than approximately 20 μm.

6. The wafer-level package device as recited in claim 5, wherein the redistribution layer metal line includes a redistribution layer metal line with a width of approximately 12 μm.

7. An electronic device, comprising:
a printed circuit board; and
a wafer-level-package device coupled to the printed circuit board, the wafer-level package device including
a substrate;
a metal seed layer disposed on the substrate;
a redistribution layer structure disposed on the metal seed layer, where the seed layer has been dry-etched and at least one exposed edge of the metal seed layer is at least substantially flush with a corresponding exposed edge of the redistribution layer structure.

8. The electronic device as recited in claim 7, wherein the substrate includes a photo-definable dielectric film.

9. The electronic device as recited in claim 7, wherein the metal seed layer includes a titanium seed layer.

10. The electronic device as recited in claim 7, wherein the redistribution layer structure includes a plated copper redistribution layer structure.

11. The electronic device as recited in claim 7, wherein the redistribution layer structure includes a redistribution layer metal line with a width less than approximately 20 μm.

12. The electronic device as recited in claim 11, wherein the redistribution layer metal line includes a redistribution layer metal line with a width of approximately 12 μm.

13. A process comprising:
depositing a metal seed layer on a substrate;
placing a photoresist layer on the metal seed layer;
depositing a redistribution layer structure on the metal seed layer;
removing the photoresist layer; and
dry-etching the metal seed layer to mitigate undercut where at least one edge of the metal seed layer is at least substantially flush with a corresponding edge of the redistribution layer structure.

14. The process as recited in claim 13, wherein depositing a metal seed layer on a substrate includes depositing a metal seed layer on a semiconductor wafer.

15. The process as recited in claim 13, wherein processing the substrate includes processing a photo-definable dielectric film.

16. The process as recited in claim 13, wherein depositing a metal seed layer includes depositing a titanium seed layer.

17. The process as recited in claim 13, wherein depositing a redistribution layer includes electroplating a copper redistribution layer structure.

18. The process as recited in claim 13, wherein depositing a redistribution layer includes depositing a redistribution layer metal line with a width of less than 20 μm.

19. The process as recited in claim 18, wherein depositing a redistribution layer metal line includes depositing a redistribution layer metal line with a width of approximately 12 μm.

20. The process as recited in claim 13, wherein dry-etching the metal seed layer includes plasma-etching the metal seed layer.
